(19) United States
(12) Patent Application Publication
(10) Pub. No.: US 2007/0198883 A1
(43) Pub. Date: Aug. 23, 2007

(54) Scan Read Block Wherein a Scan Latch Circuit and a Bit Cell Have Substantially Identical Circuit Structures

(76) Inventor: Jeong-joo Lim, Yongin-si (KR)

Correspondence Address: Frank Chau, Esq.;F. CHAU & ASSOCIATES, LLC, 130 Woodbury Road, Woodbury, NY, 11797, US

(21) Appl. No.: 11/674,436

(22) Filed: Feb. 13, 2007

(30) Foreign Application Priority Data
Feb. 21, 2006 (KR) 10-2006-0016683

(51) Int. Cl. G01R 31/28

(52) U.S. Cl. 714/726

(57) ABSTRACT

A scan read block has a relatively short latch circuit and an acceptable noise margin. The scan read block includes a bit cell array and a scan latch block. The bit cell array includes bit cells transmitting data through a corresponding bit line and inverted bit line. The data is transmitted in response to word line scan signals. The scan latch block includes scan latch circuits latching data stored in a corresponding bit cell through the bit lines and the inverted bit lines. In the scan latch block, the scan latch signal is enabled after the word line scan signals are enabled, and thereafter, data of the bit cell array is latched into a corresponding scan latch circuit during a time when the word line scan signals and the scan latch signal are both enabled.

### CROSS-REFERENCE TO RELATED APPLICATION

This application claims priority to Korean Patent Application No. 10-2006-0016683, filed on Feb. 21, 2006, in the Korean Intellectual Property Office, the disclosure of which is incorporated by reference herein in its entirety.

### BACKGROUND OF THE INVENTION

1. Technical Field

The present disclosure relates to a scan read block, and more particularly, to a scan read block wherein a scan latch circuit and a bit cell have substantially identical circuit structures.

2. Discussion of the Related Art

FIG. 1 shows a conventional scan read block of a semiconductor memory apparatus.

Referring to FIG. 1, the scan read block 100 includes a bit cell array 110, a scan latch circuit 120, a scan control circuit 130, and a latch control circuit 140.

The bit cell array 110, which includes a plurality of bit cells, outputs data of a bit cell of the plurality of bit cells through a corresponding bit line of a plurality of bit lines B0, B1, . . . , BM and a corresponding inverted bit line of a plurality of inverted bit lines B0B, B1B, . . . , BMB in response to a corresponding scan signal of a plurality of scan signals SE_0, SE_1, . . . , SE_N.

FIG. 2 is a circuit diagram of the bit cell array 110 illustrated in FIG. 1. Referring to FIG. 2, each of the bit cells of the bit cell array 110 outputs stored data through a corresponding bit line and a corresponding inverted bit line in response to a corresponding scan signal. For example, a bit cell 111 outputs stored data through a zero-th bit line B0 and a zero-th inverted bit line B0B in response to a scan signal SE_0.

FIG. 3 is an internal circuit diagram of the bit cell 111 illustrated in FIG. 2

Referring to FIG. 3, the bit cell 111 includes two inverters that constitute a latch circuit and two metal-oxide semiconductor (MOS) transistors which operate in response to the scan signal SE_0. The two MOS transistors switch the latch circuit, the bit line B0, and the inverted bit line B0B. The bit cell 111 includes 6 MOS transistors, since each of the two inverters can be implemented with 2 MOS transistors.

The scan latch circuit 120 includes a plurality of latch circuits storing and outputting data D0, D1, . . . , DM included in a bit line or an inverted bit line of the bit cell array 110 in response to a latch signal L and an inverted latch signal LB.

FIG. 4 is a circuit diagram of a latch circuit included in the scan latch circuit 120 illustrated in FIG. 1.

Referring to FIG. 4, each of the latch circuits 121 to 123 stores and outputs data included in a corresponding bit line or inverted bit line in response to the latch signal L and the inverted latch signal LB.

FIG. 5 is an internal circuit diagram of the latch circuit 121 illustrated in FIG. 4.

Referring to FIG. 5, the latch circuit 121 stores and outputs data included in a zero-th bit line B0 using two inverters and two tri-state inverters which operate in response to the latch signal L and the inverted latch signal LB.

The scan control unit 130 outputs scan signals SE_0, SE_1, . . . , SE_N in response to scan address signal SCAN0, SCAN1, . . . , SCANN and a scan enable signal EN.

FIG. 6 is a circuit diagram of the scan control circuit 130 illustrated in FIG. 1.

Referring to FIG. 6, the scan control circuit 130 includes a plurality of 2-input NAND gates 131 to 133. The NAND gates output scan signals SE_0, SE_1, . . . , SE_N by inverting phases of corresponding scan address signals SCAN0, SCAN1, . . . , SCANN, respectively, when the scan enable signal EN is high.

FIG. 7 is an internal circuit diagram of the latch control circuit 140 illustrated in FIG. 1.

Referring to FIG. 7, the latch control circuit 140 outputs the latch signal L and the inverted latch signal LB. The latch signal L is obtained by passing a latch indication signal LATCH through two inverters. Accordingly, the latch signal L has the same phase as the latch indication signal LATCH. The inverted latch signal LB is obtained by passing the latch indication signal LATCH through three inverters. Accordingly, the phase of the inverted latch signal LB is inverse to the phase of the latch indication signal LATCH.

The scan read block of FIG. 1 is generally included in a conventional single-ended bit line sense circuit. However, in the layout of the conventional circuit, the widths of each of the bit cells illustrated in FIG. 2 and each of the latch circuits illustrated in FIG. 4 are to be the same. Accordingly, a length of each of the latch circuits is increased so that the width of each of the latch circuit is not larger than the width of each of the bit cells.

### SUMMARY OF THE INVENTION

Exemplary embodiments of the present disclosure provide a scan read block for which it is not necessary to increase a length of a latch circuit. The scan read block has an acceptable noise margin.

According to an exemplary embodiment of the present invention, a scan read block comprises a bit cell array and a scan latch block. The bit cell array comprises a plurality of bit cells inputting and/or outputting data through corresponding bit lines and corresponding inverted bit lines from among a plurality of bit lines and a plurality of inverted bit lines. Data is input and/or output in response to a corresponding signal from among a plurality of word line scan signals. The scan latch block comprises a plurality of scan latch circuits. The scan latch circuits latch data stored in a corresponding bit cell through the plurality of bit lines and the plurality of inverted bit lines. The scan latch circuits latch data in response to a scan latch signal. In the scan latch block, the scan latch signal is enabled after the plurality of word line scan signals is enabled. Thereafter data of the bit cell array is latched to corresponding latch circuits during a time when the plurality of word line scan signals and the scan latch signal are enabled concurrently.

According to an exemplary embodiment of the present invention, a scan read block comprises a bit cell array, a scan latch block, a latch control circuit, and a plurality of scan control circuits. The bit cell array comprises a plurality of bit cells inputting and/or outputting data. The data is input and/or output through corresponding bit line and inverted bit line from among a plurality of bit lines and inverted bit lines in response to a corresponding signal from among a plurality of word line scan signals. The scan latch block comprises a plurality of scan latch circuits. The scan latch circuits latch data stored in a corresponding bit cell through the plurality of bit lines and the plurality of inverted bit lines. Data is latched in response to a scan latch signal. The latch control circuit outputs the scan latch signal in response to an enable signal and a latch signal. The plurality of scan control circuits output the plurality of word line scan signals in response to the enable signal and a plurality of word line selection signals. In the scan read block, the scan latch signal is enabled after the plurality of word line scan signals are enabled. Thereafter, data of the bit cell array is latched into a corresponding latch circuit during a time when the plurality of word line scan signals and the scan latch signal are enabled concurrently.

### BRIEF DESCRIPTION OF THE DRAWINGS

The above and other features of the exemplary embodiments of the present disclosure are described in detail with reference to the attached drawings in which:

FIG. 1 is an embodiment of a conventional scan read block of a semiconductor memory apparatus;

FIG. 2 is a circuit diagram of a bit cell array illustrated in FIG. 1;

FIG. 3 is a circuit diagram of a bit cell illustrated in FIG. 2;

FIG. 4 is a circuit diagram of a latch circuit included in a scan latch circuit illustrated in FIG. 1;

FIG. 5 is a circuit diagram of the latch circuit illustrated in FIG. 4;

FIG. 6 is a circuit diagram of a scan control circuit illustrated in FIG. 1;

FIG. 7 is a circuit diagram of a latch control circuit illustrated in FIG. 1;

FIG. 8 is a scan read block according to an exemplary embodiment of the present invention;

FIG. 9 is a block diagram of a scan latch block illustrated in FIG. 8;

FIG. 10 is a circuit diagram of a scan latch circuit illustrated in FIG. 9;

FIG. 11 is a block diagram of a scan control block illustrated in FIG. 8;

FIG. 12 is a view of a partial layout including the conventional scan read circuit; and

FIG. 13 is a view of a partial layout including a scan read circuit according to an exemplary embodiment of the present invention.

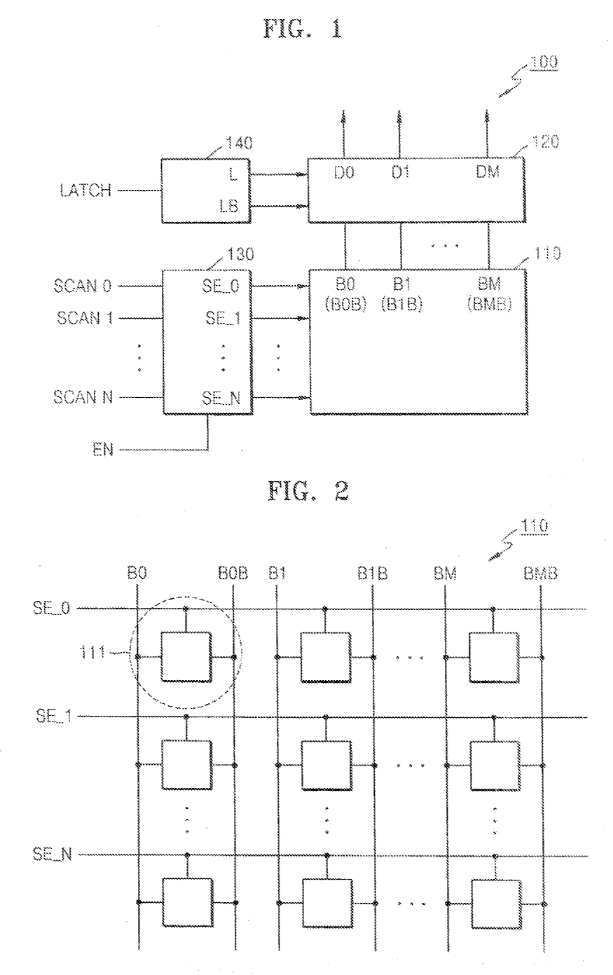

### DETAILED DESCRIPTION OF THE EXEMPLARY EMBODIMENTS

Exemplary embodiments of the present invention will be described in detail with reference to the accompanying drawings. Like reference numerals in the drawings may denote like elements.

FIG. 8 is a scan read block 800 according to an exemplary embodiment of the present invention.

Referring to FIG. 8, the scan read block 800 includes a bit cell array 810, a scan latch block 820, and a scan control block 830.

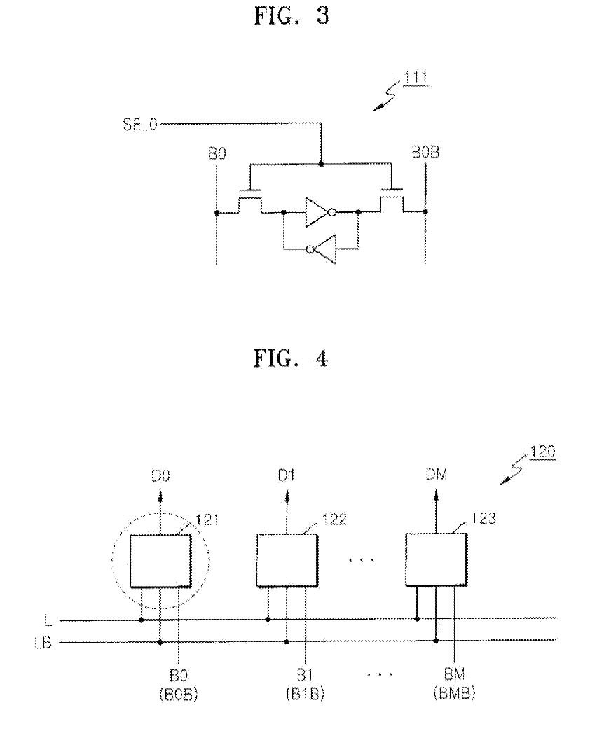

The bit cell array 810 includes a plurality of bit cells which input and/or output data through a corresponding bit line and an inverted bit line from among a plurality of bit lines and inverted bit lines. Data is input and/or output in response to a corresponding signal from among a plurality of word line scan signals SE_0, SE_1, . . . , SE_N. Structures of internal blocks of the bit cell array 810 and the bit cell can be the same as or similar to the bit cell array 110 and bit cell illustrated in FIGS. 2 and 3.

The scan latch block 820 includes a plurality of scan latch circuits latching data stored in a corresponding cell through a plurality of bit lines B0, B1, . . . , BM and a plurality of inverted bit lines B0B, B1B, . . . , BMB.

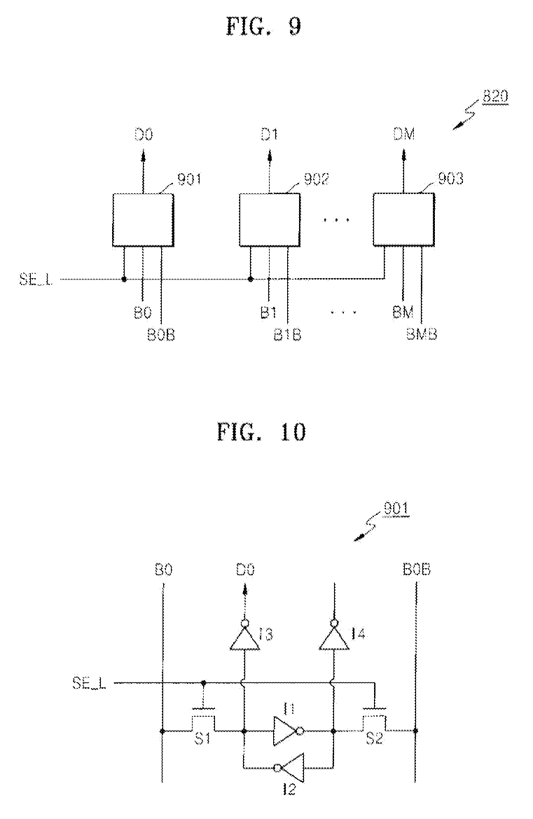

FIG. 9 is a block diagram of the scan latch block 820 illustrated in FIG. 8.

Referring to FIG. 9, the scan latch block 820 includes a plurality of scan latch circuits 901 to 903. The plurality of scan latch circuits 901 to 903 store and output data loaded in a corresponding bit line and a corresponding inverted bit line in response to a scan latch signal SE_L.

For example, a first scan latch circuit 901 stores and outputs D0 data loaded in a zero-th bit line B0 and a zero-th inverted bit line B0B in response to the scan latch signal SE_L. In the same way, an M-th scan latch circuit 903 stores and outputs data DM loaded in an M-th bit line BM and the M-th inverted bit line BMB in response to the scan latch signal SE_L.

FIG. 10 is a circuit diagram of the scan latch circuit 901 illustrated in FIG. 9.

Referring to FIG. 10, the scan latch circuit 901 includes two inverters I1 and I2 and two switches S1 and S2.

In the scan latch circuit 901 in FIG. 10, two inverters I3 and I4 are used as buffers for an output signal D0. Although there may only be one output signal D0, two inverters I3 and I4 are used in view of the symmetry of the layout. By including both inverters I3 and I4, the same process condition may be used to form other patterns.

The scan control block 830 outputs a plurality of word line scan signals SE_0, SE_1, . . . , SE_N and a scan latch signal SE_L in response to a plurality of word line selection signals SCAN0, SCAN1, . . . , SCANN, a latch signal LATCH, and an enable signal EN.

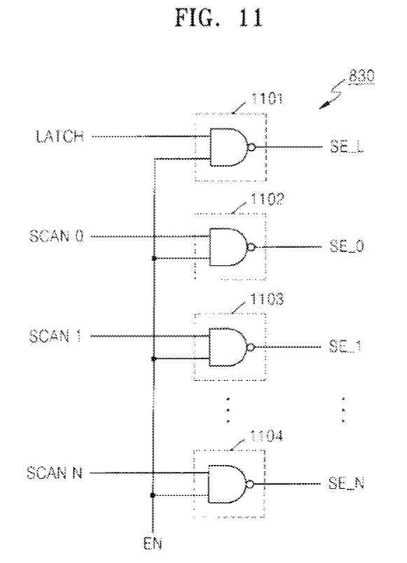

FIG. 11 is a block diagram of the scan control block 830.

Referring to FIG. 11, the scan control block 830 includes a latch control circuit 1101 and a plurality of control circuits 1102 to 1104. The latch control circuit 1101 outputs the scan latch signal SE_L in response to the enable signal EN and the latch signal LATCH. A zero-th control circuit 1102 outputs a zero-th word line scan signal SE_0 in response to the enable signal EN and zero-th word line selection signal SCAN0. A first control circuit 1103 outputs a first word line scan signal SE_1 in response to the enable signal EN and a first word line selection signal SCAN1. An N-th control circuit 1104 outputs an N-th word line scan signal SE_N in response to the enable signal EN and an N-th word line selection signal SCANN. The latch control circuit 1101 and the plurality of control circuits 1102 to 1104 can be implemented using 2-input NAND gates.

An operation of the scan read block illustrated in FIG. 8 will now be described, according to an exemplary embodiment of the present invention.

According to an exemplary embodiment of the present invention, bit cell data of a row to be scanned is latched to a latch circuit during a time when the plurality of word line scan signals and the scan latch signal are enabled concurrently.

For example, at first, data of a bit cell disposed along a word line which indicates a row is loaded into the bit line and the inverted bit line. Thereafter, the scan latch signal is enabled before the word line is disabled. The word line scan signal and the scan latch signal are enabled concurrently for a predetermined time and data of a bit cell is latched into a corresponding latch circuit through the bit line and the inverted bit line during the predetermined time. The latch data of the bit cell is stored in the latch circuit, although the word line scan signal is disabled thereafter.

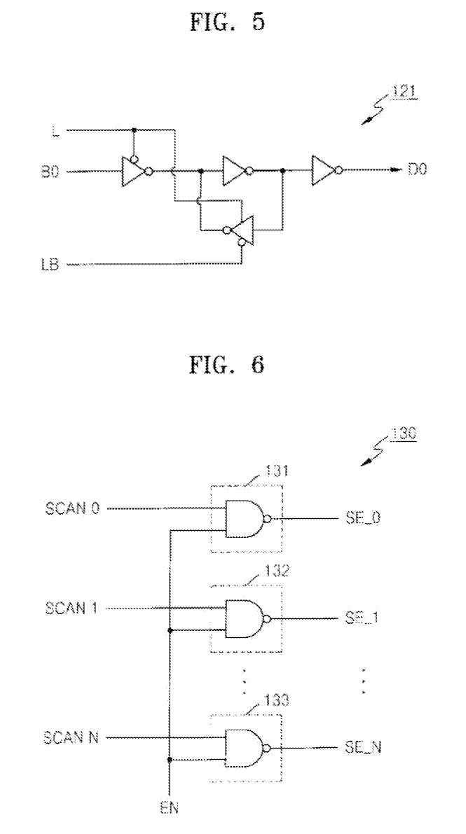

According to an exemplary embodiment of the present invention, substantially identical structures are used for the unit scan latch circuit and the unit bit cell. Since substantially identical structures for the unit scan latch circuit and the unit bit cell is used, no effort is required to match the pitches of the scan latch circuit and a corresponding bit cell. In addition, the scan latch circuit 901 has a structure simpler than the conventional scan latch circuit 121 illustrated in FIG. 5 and occupies a smaller area in a layout than the conventional scan latch circuit 121.

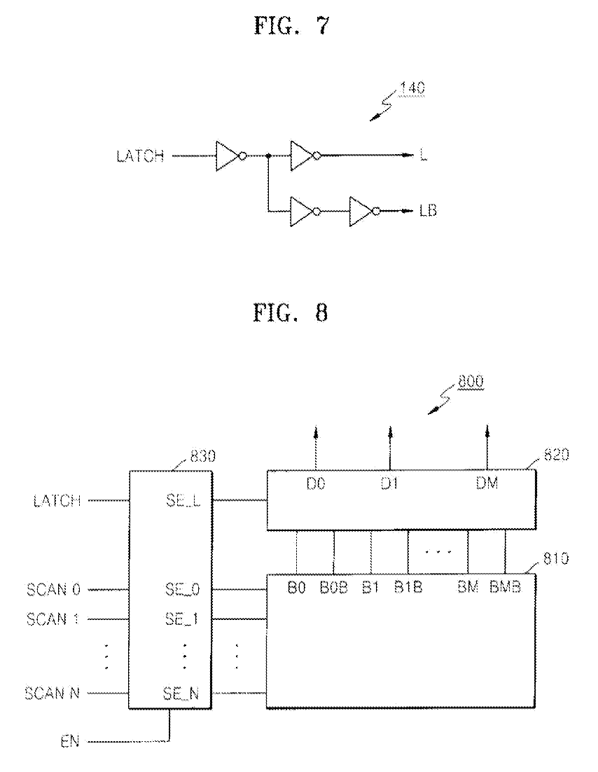

The conventional latch control circuit 140 illustrated in FIG. 7 outputs two signals L and LB and the two signals L and LB are applied to the conventional latch circuit 121. According to an embodiment of the present invention, the latch control unit 1101 illustrated in FIG. 11 outputs one signal SE_L. By using one signal line instead of two signal lines, a simpler structure can be obtained and a smaller area is occupied in a layout than in the case of the conventional scan latch circuit 121 that uses two signal lines.

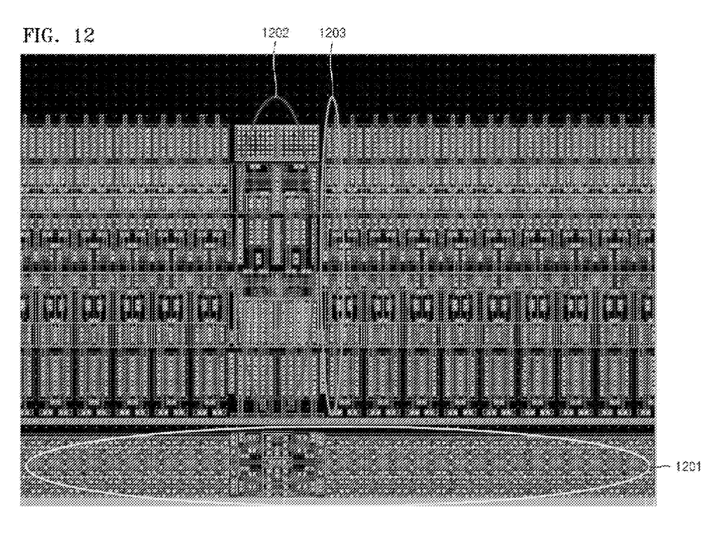

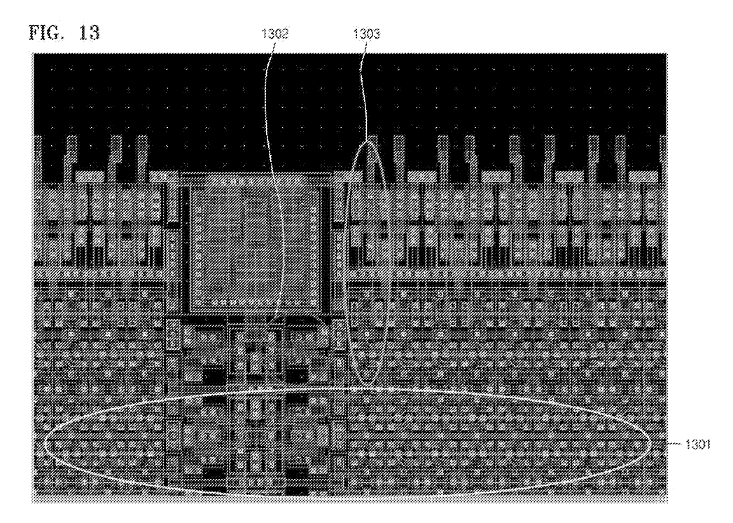

FIG. 12 is a view of a partial layout including a conventional scan read circuit.

FIG. 13 is a view of a partial layout including a scan read circuit according to an exemplary embodiment of the present invention.

Horizontal ovals illustrated in FIGS. 12 and 13 (1201 and 1301 respectively) represent areas in which bit cell arrays are disposed, a left vertical oval or circle (1202 and 1302 respectively) illustrated above the bit cell array represents an area in which the latch control circuit is disposed and a right vertical oval (1203 and 1303 respectively) represents an area in which the scan latch circuit is disposed.

Referring to FIGS. 12 and 13, it is apparent that the area occupied in the layout of the scan read circuit according to an exemplary embodiment of the present invention (as seen in FIG. 13) by the scan latch circuit is smaller than the area occupied in the layout for the conventional scan read circuit (as seen in FIG. 12).

In the scan read block according to an exemplary embodiment of the present invention, an area occupied in the layout by the scan latch circuit may be reduced by using substantially identical structures for a unit bit cell and the scan latch circuit. A noise margin may be increased by latching data of bit cells from the bit cell array through bit lines and inverted bit lines.

While the present disclosure has been particularly shown and described with reference to exemplary embodiments thereof, the exemplary embodiments are descriptive and non-limiting. Accordingly, it will be understood by those skilled in the art that various changes in form and details may be made without departing from the spirit and scope of the present invention.

What is claimed is:

1. A scan read block comprising:
a bit cell array comprising a plurality of bit cells, each of the plurality of bit cells having a corresponding bit line from among a plurality of bit-lines, and a corresponding inverted bit line from among a plurality of inverted bit lines, wherein each of the plurality of bit cells communicates data through the corresponding bit line and the corresponding inverted bit line in response to a corresponding signal from among a plurality of word line scan signals; and
a scan latch block comprising a plurality of scan latch circuits, wherein each scan latch circuit latches data stored in a corresponding bit cell through the corresponding bit line and the corresponding inverted bit line in response to a scan latch signal,
wherein the scan latch signal is enabled after the plurality of word line scan signals are enabled and data of the bit cell array is latched to a corresponding scan latch circuits during a time when the plurality of word line scan signals and the scan latch signal are both enabled.

2. The scan read block of claim 1, wherein the communication of data through the bit lines by the bit cells comprises inputting the data.

3. The scan read block of claim 1, wherein the communication of data through the bit lines by the bit cells comprises outputting the data.

4. The scan read block of claim 1, wherein the scan latch block includes:
a first scan latch circuit latching data of a zero-th bit line and a zero-th inverted bit line output from the bit cell array in response to the scan latch signal; and
a second scan latch circuit latching data of a first bit line and a first inverted bit line output from the bit cell array in response to the scan latch signal.

5. The scan read block of claim 4, wherein each of the first and second scan latch circuits has a substantially identical structure as a first bit cell and a second bit cell from among the plurality of bit cells.

6. The scan read block of claim 5, wherein each of the first and second scan latch circuits comprises:
a latch circuit storing and communicating data through two input/output terminals;
a first switch switching between the corresponding bit line and one of the input/output terminals of the latch circuit in response to the scan latch signal; and
a second switch switching between the corresponding inverted bit line and the other of the input/output terminals of the latch circuit in response to the scan latch signal.

7. The scan read block of claim 6, wherein the latch circuit comprises:
a first inverter of which an input terminal is connected to one terminal of the latch circuit, and an output terminal is connected to the other terminal of the latch circuit; and
a second inverter of which an input terminal is connected to the output terminal of the first inverter, and an output terminal is connected to the input terminal of the first inverter.

8. The scan read block of claim 6, wherein
the first switch is a first MOS transistor of which a drain terminal is connected to a corresponding bit line, and a source terminal is connected to one of the input/output terminals of the latch circuit and a gate terminal receives the scan latch signal; and
the second switch is a second MOS transistor of which a drain terminal is connected to a corresponding inverted bit line, a source terminal is connected to the other of the input/output terminals of the latch circuit, and a gate terminal receives the scan latch signal.

9. The scan read block of claim 6, wherein
the first switch is a first MOS transistor of which a source terminal is connected to a corresponding bit line, and a drain terminal is connected to one of the input/output terminals of the latch circuit and a gate terminal receives the scan latch signal; and
the second switch is a second MOS transistor of which a source terminal is connected to a corresponding inverted bit line, a drain terminal is connected to the other of the input/output terminals of the latch circuit, and a gate terminal receives the scan latch signal.

10. The scan read block of claim 6, wherein the scan latch circuit further comprises:
a third inverter of which a corresponding input terminal receives an output signal of one of the input/output terminals of the latch circuit; and
a fourth inverter of which a corresponding input terminal receives an output signal of the other of the input/output terminals of the latch circuit.

11. The scan read block of claim 1, further comprising a scan control block outputting corresponding word line scan signals from among the plurality of word line scan signals and the scan latch signal in response to a plurality of word line selection signals, a latch signal, and an enable signal.

12. The scan read block of claim 11, wherein the scan control block comprises:
a latch control circuit outputting the scan latch signal in response to the enable signal and the latch signal;
a zero-th control circuit outputting a zero-th word line scan signal in response to the enable signal and the zero-th word line selection signal; and
a first control circuit outputting a first word line scan signal in response to the enable signal and the first word line selection signal.

13. The scan read block of claim 12, wherein each of the latch control circuit, the zero-th control circuit and the first control circuit comprises a two-input NAND gate.

14. A scan read block comprising:
a bit cell array comprising a plurality of bit cells, each of the plurality of bit cells having a corresponding bit line from among a plurality of bit lines, and a corresponding inverted bit line from among a plurality of inverted bit lines, wherein each of the plurality of bit cells communicates data through the corresponding bit line and the corresponding inverted bit line in response to a corresponding signal from among a plurality of word line scan signals;
a scan latch block comprising a plurality of scan latch circuits, wherein each scan latch circuit latches data stored in a corresponding bit cell through the corresponding bit line and the corresponding inverted bit line in response to a scan latch signal;
a latch control circuit outputting the scan latch signal in response to an enable signal and a latch signal; and
a plurality of scan control circuits outputting the plurality of word line scan signals in response to the enable signal and a plurality of word line selection signals,
wherein the scan latch signal is enabled after the plurality of word line scan signals are enabled, and data of the bit cell array is latched into a corresponding scan latch circuit during a time when the plurality of word line scan signals and the scan latch signal are both enabled.

15. The scan read block of claim 14, wherein the communication of data through the bit lines by the bit cells comprises inputting the data.

16. The scan read block of claim 14, wherein the communication of data through the bit lines by the bit cells comprises outputting the data.

17. The scan read block of claim 14, wherein structures of the scan latch circuit and the bit cell are substantially identical.

18. The scan read block of claim 14, wherein structures of the scan control circuit and the latch control circuit are substantially identical.

19. A semiconductor memory apparatus comprising the scan read block of claim 14.
